(19) United States
(12) Patent Application Publication
(10) Pub. No.: US 2008/0111197 A1
(43) Pub. Date: May 15, 2008

(54) SEMICONDUCTOR DEVICE INCLUDING A MISFET HAVING DIVIDED SOURCE/DRAIN REGIONS

(75) Inventor: Noriaki MIKASA, Tokyo (JP)

Correspondence Address: SCULLY SCOTT MURPHY & PRESSER, PC, 400 GARDEN CITY PLAZA, SUITE 300, GARDEN CITY, NY, 11530, US

(73) Assignee: ELPIDA MEMORY, INC., Tokyo (JP)

(21) Appl. No.: 11/934,348

(22) Filed: Nov. 2, 2007

(30) Foreign Application Priority Data
Nov. 9, 2006 (JP) 2006-303558

(51) Int. Cl. H01L 29/78; H01L 21/336

(52) U.S. Cl. 257/386; 438/296; 257/E21.409; 257/E29.255

(57) ABSTRACT

A MISFET includes source/drain regions each including a plurality of divided substrate regions divided by intervening insulation films, and a selectively-grown silicon layer formed on the divided substrate regions and intervening insulation film to electrically couple together the divided substrate regions. The resultant MISFET has a reduced junction capacitance across the p-n junction of the source/drain regions, to improve the operation speed of the MISFET.

This application is based upon and claims the benefit of priority from Japanese patent application No. 2006-303558, the disclosure of which is incorporated herein in its entirety by reference.

### BACKGROUND OF THE INVENTION

(a) Field of the Invention

The present invention relates to a semiconductor device including a MISFET having divided substrate regions and, more particularly, to a technique for manufacturing a MISFET having a reduced junction capacitance across the p-n junction of the source/drain regions.

(b) Description of the Related Art

Semiconductor devices including MISFETs formed on a silicon substrate are the mainstream of the current semiconductor devices. FIGS. 7 and 8 show top plan view and sectional view, respectively, of a conventional MISFET. A process for manufacturing the MISFET of FIGS. 7 and 8 includes the steps of forming an element isolation region 20 having a shallow-trench-isolation (STI) structure in the surface region of a p-type silicon substrate 10, for example, and forming source/drain regions 16 and 17 in the device regions 11 isolated from one another by the element isolation region 20. Gate electrodes 12 are then formed on the device regions 11, with an intervention of a gate oxide film (not sown), at the location interposed between the source region 16 and the drain regions 17.

The source/drain regions 16 and 17 are connected to respective overlying interconnection layers via contact plugs 18 and 19, respectively. A p-n junction is formed between each of the n-type source/drain regions 16 and 17 and the surrounding area including a channel region 15, which underlies the gate electrode 12 and is located between the source region 16 and the drain region 17. The p-n junction involves a junction capacitance which prevents a high operational speed of the MOSFET. Thus, it is essential to reduce the junction capacitance for enhancing the operational speed of the MOSFET.

As depicted in FIGS. 7 and 8, it is assumed here that W1, L1 and D1 are the width, length and depth, respectively, of the source/drain regions 16 and 17. The W1 also represents the width of the device region 11. The surface area of the p-n junction of each of the source/drain regions 16 and 17 is represented by the sum of the side area and the bottom area of the each of the source/drain regions 16 and 17. Thus, the total area A1 of the p-n junction in the MISFET is substantially represented by:

A1=(W1×L1+W1D1)×2=(L1+D1)×W1×2.

### Thus, for reducing the total area A1, it is effective to reduce the width W1 of the source/drain regions in the above formula.

There are some publications that may be considered to relate to the technique of the present embodiment, including Patent Publications JP-1997-74205A, -1998-65164A and -2004-6731A.

Employment of a smaller width W1 for the source/drain regions may have the following disadvantages:

(1) The resistance of the source/drain regions increases with a decrease in the width. For example, if the width is reduced from W1 to W2, as depicted in FIG. 9 showing a comparative example of MISFET, the resultant ON resistance of the source/drain regions is reduced down to W2/W1 of the original resistance. The increase of the ON resistance of the source/drain regions in the comparative example reduces the ON current of the MISFET and degrades the response characteristic thereof.
(2) The contact area of the source/drain regions is reduced, whereby the number of contact plugs provided for the source/drain regions is reduced due to the restriction by the narrow top surface of the source/drain regions. The reduced number of contact plugs reduces the ON current of the MISFET and degrades the response characteristic thereof as well.

There is a demand for a technique of reducing the width of the source/drain diffused regions while suppressing the increase of the ON resistance and contact resistance of the MISFET.

### SUMMARY OF THE INVENTION

In view of the above, it is an object of the present invention to provide a semiconductor device including a MISFET having a reduced area for the p-n junction while suppressing an increase in the ON resistance and contact resistance of the MISFET, and to thereby to provide a MISFET having an increased operational speed.

The present invention provides a semiconductor device including: a semiconductor substrate; and a metal-insulator-semiconductor field-effect transistor (MISFET) including source and drain regions and a channel region in a device area of the semiconductor substrate, at least one of the source and drain regions including: a plurality of divided substrate regions formed in the semiconductor substrate and isolated from one another by at least one intervening insulation film; and a semiconductor layer formed on the divided substrate regions and the intervening insulation film to electrically couple together the divided substrate regions.

The present invention also provides a method for manufacturing a semiconductor device including: forming an isolation region in a semiconductor substrate to divide the semiconductor substrate into a plurality of device areas; forming at least one intervening insulation film in the device area to isolate the device area into a plurality of divided substrate regions; depositing a semiconductor layer on the intervening insulation film and the divided substrate regions; implanting impurities into the semiconductor layer and at least a top portion of the divided substrate regions to form therefrom source and drain regions and a channel region in the device area; and forming a gate electrode in association with the source and drain regions and the channel region to configure a metal-insulator-semiconductor field-effect-transistor (MISFET).

The above and other objects, features and advantages of the present invention will be more apparent from the following description, referring to the accompanying drawings.

### BRIEF DESCRIPTION OF THE DRAWINGS

FIG. 1 is a top plan view of a semiconductor device according to a first embodiment of the present invention.

FIG. 2 is a sectional view taken along line II-II in FIG. 1.

FIG. 3 is a sectional view taken along line III-III in FIG. 2.

FIG. 4 is a schematic top plan view of the divided device area of the MOSFET.

FIG. 5 is a top plan view of the semiconductor device of FIG. 1 at the stage after depositing a selectively-grown silicon layer on the divided device area.

FIG. 6 is a sectional view taken along line VI-VI in FIG. 5.

FIG. 7 is a top plan view of a conventional semiconductor device.

FIG. 8 is a sectional view taken along line VIII-VIII in FIG. 7.

FIG. 9 is a top plan view of the conventional semiconductor device of FIG. 7 after reducing the width of the source/drain regions.

### PREFERRED EMBODIMENT OF THE INVENTION

Now, an exemplary embodiment of the present invention will be described with reference to accompanying drawings, wherein similar constituent elements are designated by similar reference numerals throughout the drawings.

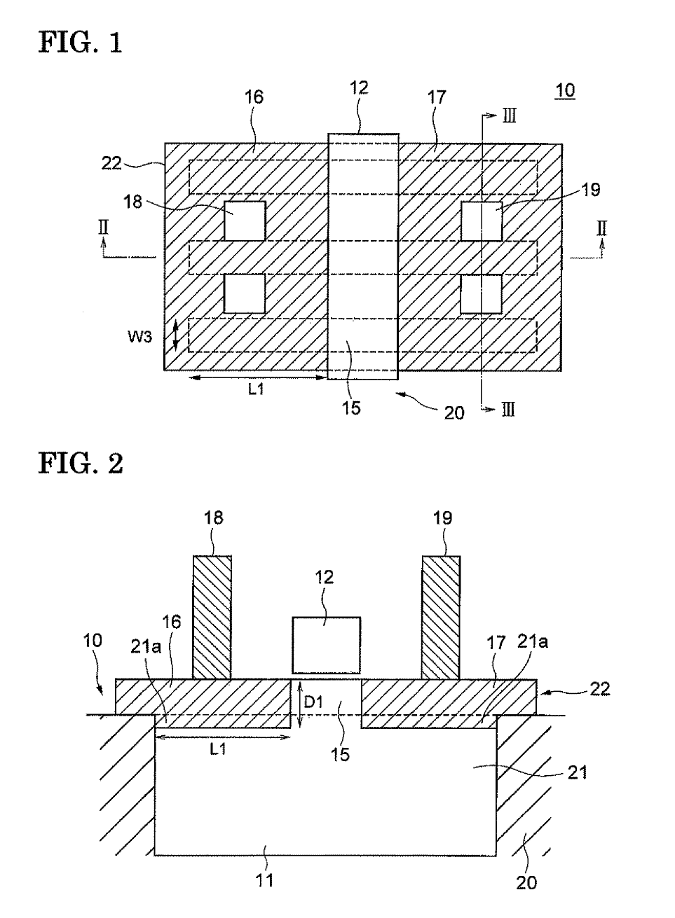

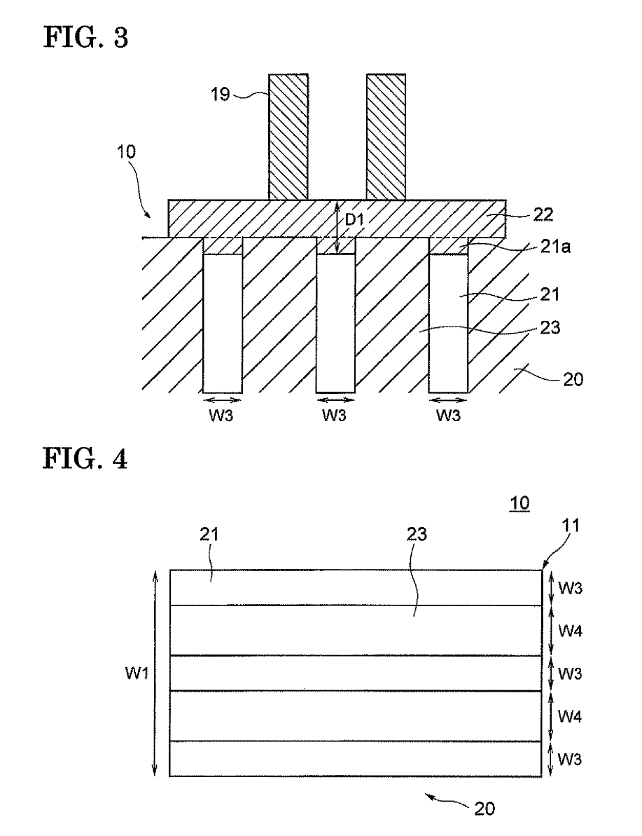

FIG. 1 is a top plan view of the device area of a MISFET in a semiconductor device according to an embodiment of the present invention. FIGS. 2 and 3 show sectional views taken along lines II-II and III-III, respectively, in FIG. 1. A semiconductor substrate 10 of the semiconductor device includes a plurality of device areas, which are isolated from one another by a STI structure 20, and one of which is shown in the drawings. The MISFET formed in the device area includes source/drain regions 16, 17 each configured by a plurality of divided diffused regions 21a and a selectively-grown silicon layer 22 deposited on the divided diffused regions 21a to electrically couple together the divided diffused regions 21a.

The divided diffused regions 21a have a shape of rectangular plate and are divided from one another by an intervening insulation film 23 interposed between adjacent two of the divided diffused regions. Each divided diffused region 21a is formed in a corresponding one of a plurality of divided substrate regions formed in the device area 11 of the silicon substrate 10. The selectively-grown silicon layer 22 has a length and a width slightly larger than the length and width, respectively, of the device area 11. A channel region 15 of the MISFET underlies a gate electrode 12 and is located between the source region 16 and the drain region 17.

FIG. 4 shows a top plan view of the divided substrate regions 21 in the device area 11 of the MISFET. The divided substrate regions 21 are formed in the step of forming the STI structure 20, which isolates the silicon substrate 10 into the device areas 11 for the MISFETs, by concurrently forming the intervening insulating film 23 to separate each ordinary device area 11 into a plurality (three, in this example) of divided substrate regions 21. The top portion of the divided substrate regions 21 is doped with impurities to form the divided diffused regions 21a.

In FIG. 4, the divided substrate regions 21 have a width W3, and are separated by the intervening insulating film 23 having a width of W4. The device area 11 has a total width W1 where W1=3×W3+2×W4.

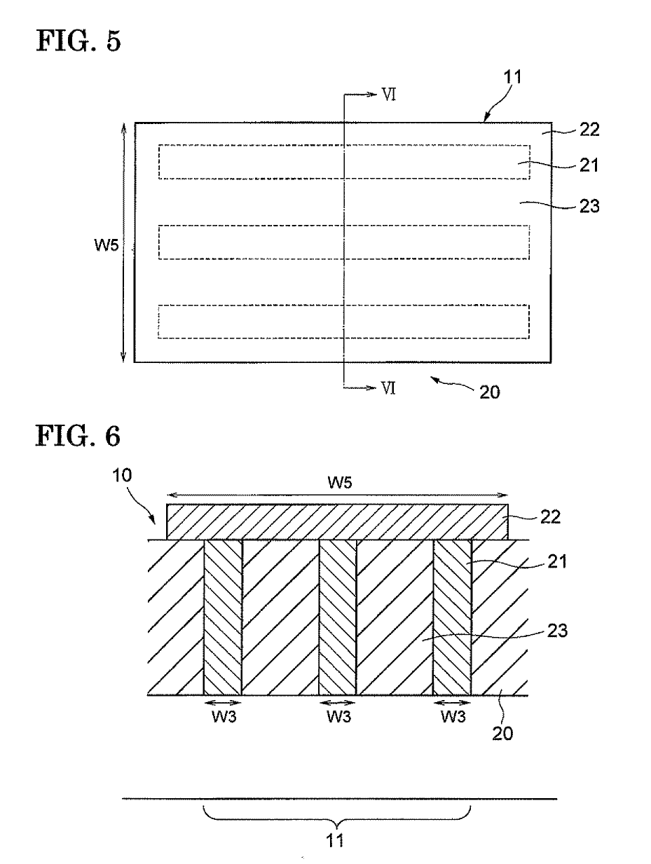

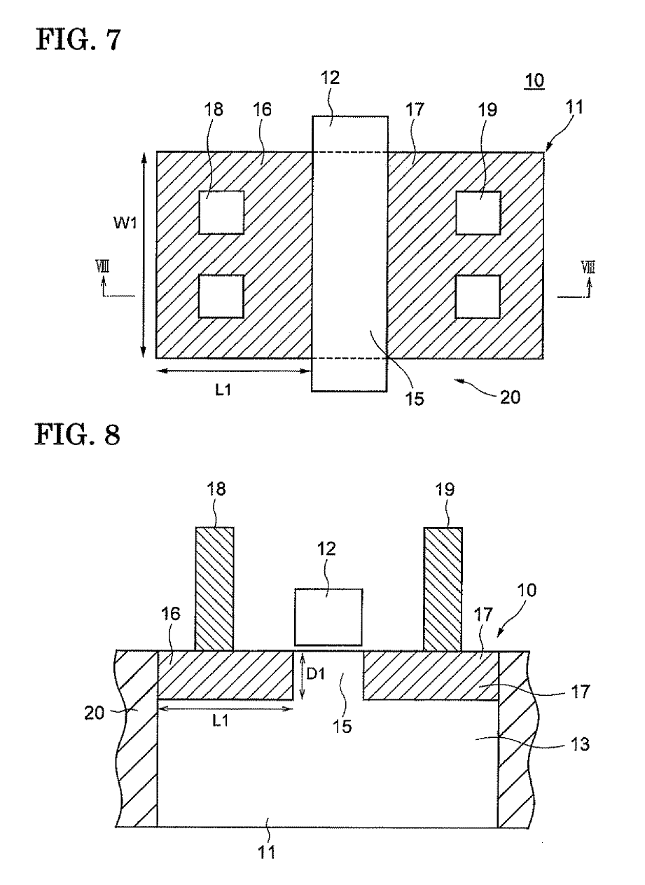

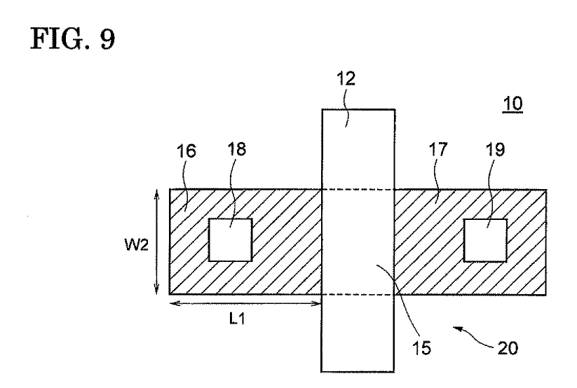

FIG. 5 shows the selectively-grown silicon layer 22 together with the divided substrate regions 21, which are depicted by a dotted line. The selectively-grown silicon layer 22 is deposited on the divided substrate regions 21 and the intervening insulating film 23 interposed between the divided substrate regions 21, by using a selective, epitaxial growth technique. The selectively-grown silicon layer 22 thus deposited electrically couples together the divided diffused regions 21a formed in a top portion of the divided substrate regions 21.

FIG. 6 is a sectional view taken along line VI-VI in FIG. 5 at the stage immediately after the growth of selectively-grown silicon layer 22. The divided substrate regions 21 have a top surface in contact with the bottom surface of the selectively-grown silicon layer 22, whereby the divided substrate regions 21 are electrically coupled together by the selectively-grown silicon layer 22. The selectively-grown silicon layer 22 has a width W5 which is slightly larger than the width of W1 of the device area 11 of the MISFET.

Back to FIGS. 1 to 3, the MISFET includes n-type source/drain regions 16 and 17, a p-type channel region 15 formed therebetween, and a gate electrode 12 overlying the p-type channel region 15, with an intervention of a gate oxide film (not shown). Two contact plugs 18, 19 are formed on the surface of each of the source/drain regions 16m 17, similarly to the conventional source/drain regions having a width of W1.

Each of the source/drain regions 16, 17 and channel region 15 is configured by a portion of the selectively-grown silicon layer 22 and a top portion of the divided substrate regions 21. For example, as shown in FIG. 2, impurities are introduced into the top portion of the divided substrate region 21 together with the selectively-grown silicon layer 22, to form source/drain regions 16, 17 including the selectively-grown silicon layer 22 and divided diffused regions 21a.

The total area A2 of the p-n junction of the source/drain regions of the MISFET is the sum of the bottom area and the side area and thus expressed by:

A2=W3×L1×N)+(W1×D1)×2,

where N, W3, L1 and D1 are the number of the divided diffused regions, width of the divided diffused regions, length of the source/drain regions in the extending direction of the channel region, and depth of the source/drain regions or channel region, respectively.

Accordingly, the difference between the area A1 of the p-n junction in the conventional source/drain regions and the area A2 of the p-n junction in the inventive source/drain regions is expressed by:

$$\begin{matrix}A 1 - A 2 = ( L 1 + D 1 ) \times W 1 \times 2 - ( ( W 3 \times L 1 \times N ) + ( D 1 + W 1 ) ) \times 2 \\ = L 1 \times ( W 1 - W 3 \times N ) \times 2\end{matrix}$$

In the above formula, (W1−W3×N) is equivalent to the sum of the intervals W4 between the divided diffused regions 21a, which is equal to W4×(N−1). In the present embodiment the significant difference between W1 and W3 allows a suitable selection of the depth D1 of the source/drain regions 16, 17 to reduce the area of the p-n junction, thereby reducing the junction capacitance. The reduction in the coupling capacitance of the p-n junction is achieved by selecting the depth D1 of the source/drain regions 21a to be significantly larger than the thickness of the selectively-grown silicon layer 22, and thus forming the divided diffused regions 21a from at least a part of the divided substrate regions 21.

In the present embodiment, the width W5 of the selectively-grown silicon layer 22 may be equal to or slightly larger than the width of the device area 11, which is equal to the width W1 of the conventional source/drain regions. This suppresses an increase in the resistance of the source/drain regions. Accordingly, the area of top surface of the source/drain regions is equivalent to or larger than the area of top surface of the conventional source/drain regions. This prevents a reduction in the number of contact plugs to be formed on the source/drain regions. Thus, the MISFET in the present embodiment is superior in the ON current and contact resistance to the comparative example of MISFET having a smaller width for the source/drain regions, to thereby suppress degradation of the response characteristic of the MISFET.

In accordance with the above embodiment since the source/drain regions include a plurality of divided diffused regions isolated by the intervening insulation film and electrically coupled by an overlying silicon layer doped with impurities, the total area of the p-n junction involved with the source/drain regions can be reduced compared to the case where the source/drain regions were not divided by the intervening insulation film. The reduction of the total area of the p-n junction reduces the coupling capacitance across the p-n junction, to thereby increase the operational speed of the MISFET. In addition, since the area of the top surface of the source/drain regions is not reduced, the umber of contact plugs to be formed on the source/drain regions is not reduced.

The division of the diffused region may be performed in the direction normal to the extending direction of the channel region as in the above embodiment, or may be parallel thereto. Division in the direction normal to the extending direction is preferable, because the distribution of the ON current is superior to the case of the divided direction which is parallel to the extending direction. The selectively-grown silicon layer does not require a photoresist film for the deposition step thereof.

Although the Patent Publications as mentioned before describe divided diffused regions, these publications do not describe a semiconductor layer formed on the divided diffused regions to electrically couple together the divided diffused regions.

A process for manufacturing the semiconductor device of the above embodiment will be described hereinafter. First, an etching treatment is conducted on the surface portion of a silicon substrate to form a trench, followed by deposition of a silicon oxide film in the trench to form the STI structure 20 and the intervening insulation film 23. Thus, device areas 11 including therein a plurality of divided substrate regions 21 are obtained in the silicon substrate.

Thereafter, as shown in FIG. 5, the selectively-grown silicon layer 22 is deposited on top of the divided substrate region 21 and intervening insulation films 23 by using a selective epitaxial technique. Impurities are then introduced into the channel region for adjusting the threshold of the MISFET. Subsequently, a gate insulation film and gate electrodes (not shown) are formed on the selectively-grown silicon layer 22, and ion-implantation is conducted using the gate electrodes as a mask, thereby forming source/drain regions 16, 17 as shown in FIG. 2. The acceleration energy for the introduction of impurities is such that the impurities are introduced into the selectively-grown silicon layer 22 and also into the top portion of the divided substrate regions 21 after penetrating the selectively-grown silicon layer 22. Thus, source/drain regions and channel region are formed in the selectively-grown silicon layer 22 and a portion 21a of the divided substrate regions 21. Subsequently, an interlevel dielectric film is formed thereon, and etched using a photolithographic technique to form contact holes therein. The contact holes are then filled with contact plugs in contact with the selectively-grown silicon layer 22, as shown in FIGS. 1 to 3.

In the above embodiment an n-type MISFET is exemplified; however, the present invention may be applied to a p-type MISFET. In this case, a p-type silicon substrate may be used, and the p-type MISFET is formed in an n-type well, for example, formed in the p-type silicon substrate. The STI structure and the intervening insulation films may be formed in separate steps. In this case, the STI structure and intervening insulation films may have different depths.

Although the above embodiment is such that the source/drain regions and corresponding channel region are formed in the common divided substrate regions; however, the channel region may be formed in a single area without division. The silicon layer is formed by a selective growth technique; however, the silicon layer may be formed by another conventional technique. The order of the steps in the process may be modified as desired from the above embodiment of the present invention.

While the invention has been particularly shown and described with reference to exemplary embodiment and modifications thereof the invention is not limited to these embodiment and modifications. It will be understood by those of ordinary skill in the art that various changes in form and details may be made therein without departing from the spirit and scope of the present invention as defined in the claims.

What is claimed is:

1. A semiconductor device comprising: a semiconductor substrate; and a metal-insulator-semiconductor field-effect transistor (MISFET) including source and drain regions and a channel region in a device area of said semiconductor substrate, at least one of said source and drain regions including:
a plurality of divided substrate regions formed in said semiconductor substrate and isolated from one another by at least one intervening insulation film; and
a semiconductor layer formed on said divided substrate regions and said intervening insulation film to electrically couple together said divided substrate regions.

2. The semiconductor device according to claim 1, wherein said intervening insulation film has a depth substantially equal to a depth of an isolation insulation film dividing said semiconductor substrate into a plurality of said device area.

3. The semiconductor device according to claim 1, wherein said divided substrate regions are divided from one another in a direction perpendicular to an extending direction of said channel region.

4. The semiconductor device according to claim 1, wherein said semiconductor layer is a selectively-grown silicon layer doped with a dopant.

5. The semiconductor device according to claim 1, wherein said divided substrate regions are doped with a dopant introduced through said silicon layer.

6. A method for manufacturing a semiconductor device comprising:
forming an isolation region in a semiconductor substrate to divide said semiconductor substrate into a plurality of device areas;
forming at least one intervening insulation film in said device area to isolate said device area into a plurality of divided substrate regions;
depositing a semiconductor layer on said intervening insulation film and said divided substrate regions;
implanting impurities into said semiconductor layer and at least a top portion of said divided substrate regions to form therefrom source and drain regions and a channel region in said device area; and
forming a gate electrode in association with said source and drain regions and said channel region to configure a metal-insulator-semiconductor field-effect-transistor (MISFET).

7. The method according to claim 6, wherein said isolation region forming and said intervening insulation film forming are performed in a common step.
